(19) United States
(12) Patent Application Publication
(10) Pub. No.: US 2026/0006957 A1
(43) Pub. Date: Jan. 1, 2026

(54) DISPLAY PANEL AND DISPLAY DEVICE

(71) Applicant: Tianma Advanced Display Technology Institute (Xiamen) Co.,Ltd., Xiamen (CN)

(72) Inventors: Fanqing MENG, Xiamen (CN); Zhenyu JIA, Xiamen (CN)

(21) Appl. No.: 18/817,661

(22) Filed: Aug. 28, 2024

(30) Foreign Application Priority Data
Jun. 26, 2024 (CN) 202410840705.8

(51) Int. Cl. H01L 33/62; H01L 25/075

(52) U.S. Cl. CPC H10H 20/857; H01L 25/0753

(57) ABSTRACT

A display panel and a display device are provided. The display panel includes a driving backplane and a connection member located on one side of the driving backplane. The driving backplane includes a substrate; a circuit layer over the substrate; a first film layer located on a side of the circuit layer away from the substrate, and a first inorganic protective layer located on a side of the first film layer away from the substrate. The first film layer includes a planarization layer and a first electrode layer, and the first electrode layer includes a first electrode; and at least a portion of the first electrode is exposed by the first inorganic protective layer, and the connection member is electrically connected to the first electrode.

### CROSS-REFERENCE TO RELATED APPLICATION

This application claims the priority of Chinese Patent Application No. 202410840705.8, filed on Jun. 26, 2024, the content of which is incorporated by reference in its entirety.

### TECHNICAL FIELD

The present disclosure generally relates to the field of display technologies and, more particularly, relates to a display panel and a display device.

### BACKGROUND

The driving backplane of a display panel is provided with structures such as functional circuits, functional wirings and lead-out electrodes, etc. The lead-out electrodes are used to electrically connect with the light-emitting element or driving structure such as the driving chip and the printed circuit board.

However, the oxidation resistance of the driving backplane is not as expected, and the lead-out electrodes are easily oxidized, thereby affecting the signal transmission between the driving backplane and the light-emitting element or the driving structure. The present disclosed display panels and display devices are direct to solve such a problem and other problems in the arts.

### SUMMARY

One aspect of the present disclosure provides a display panel. The display panel includes a driving backplane; and a connection member located on one side of the driving backplane. The driving backplane includes a substrate; a circuit layer over the substrate; and a first film layer located on a side of the circuit layer away from the substrate. The first film layer includes a planarization layer and a first electrode layer, and the first electrode layer includes a first electrode. The driving backplane also includes a first inorganic protective layer located on a side of the first film layer away from the substrate. At least a portion of the first electrode is exposed by the first inorganic protective layer, and the connection member is electrically connected to the first electrode.

Another aspect of the present disclosure includes a display device. The display device includes a display panel. The display panel includes a driving backplane; and a connection member located on one side of the driving backplane. The driving backplane includes a substrate; a circuit layer over the substrate; and a first film layer located on a side of the circuit layer away from the substrate. The first film layer includes a planarization layer and a first electrode layer, and the first electrode layer includes a first electrode. The driving backplane also includes a first inorganic protective layer located on a side of the first film layer away from the substrate. At least a portion of the first electrode is exposed by the first inorganic protective layer, and the connection member is electrically connected to the first electrode.

Other aspects of the present disclosure can be understood by those skilled in the art in light of the description, the claims, and the drawings of the present disclosure.

### BRIEF DESCRIPTION OF THE DRAWINGS

To illustrate the technical solutions in the embodiments of the present disclosure more clearly, the following briefly introduces the accompanying drawings used in the description of the embodiments. Obviously, the accompanying drawings in the following description are only some embodiments of the present disclosure, for those of ordinary skill in the art, other drawings can also be obtained from these drawings without creative effort.

FIG. 1 illustrates an exemplary display panel according to various disclosed embodiments of the present disclosure;

FIG. 2 illustrates an exemplary driving backplane according to various disclosed embodiments of the present disclosure;

FIG. 3 illustrates a top view of a first organic protective layer, a first electrode and a first connection hole according to various disclosed embodiments of the present disclosure;

FIG. 4 illustrates a top view of an exemplary driving backplane according to various disclosed embodiments of the present disclosure;

FIG. 5 illustrates a top view of another exemplary driving backplane according to various disclosed embodiments of the present disclosure;

FIG. 6 illustrates a top view of another exemplary driving backplane according to various disclosed embodiments of the present disclosure;

FIG. 7 illustrates a top view of another exemplary driving backplane according to various disclosed embodiments of the present disclosure;

FIG. 8 illustrates an exemplary comparison between the size of a first via hole and a second via hole according to various disclosed embodiments of the present disclosure;

FIG. 9 illustrates a top view of a first inorganic protective layer, a first electrode, a second electrode, a first via hole and a second via hole according to various disclosed embodiments of the present disclosure;

FIG. 10 illustrates a top view of another exemplary driving backplane according to various disclosed embodiments of the present disclosure;

FIG. 11 illustrates a top view of a first electrode, a first connection hole and a second connection hole according to various disclosed embodiments of the present disclosure;

FIG. 12 illustrates another exemplary display panel according to various disclosed embodiments of the present disclosure;

FIG. 13 illustrates another exemplary display panel according to various disclosed embodiments of the present disclosure;

FIG. 14 illustrates another top view of a first electrode, a first connection hole and a second connection hole corresponding to FIG. 13;

FIG. 15 illustrates another exemplary display panel according to various disclosed embodiments of the present disclosure;

FIG. 16 illustrates another top view of a first electrode, a first connection hole and a second connection hole corresponding to FIG. 15;

FIG. 17 illustrates another exemplary display panel according to various disclosed embodiments of the present disclosure;

FIG. 18 illustrates another exemplary display panel according to various disclosed embodiments of the present disclosure;

FIG. 19 illustrates a top view of a first electrode and a first power line according to various disclosed embodiments of the present disclosure;

FIG. 20 illustrates a top view of a connection signal line, a first connection electrode, a second connection electrode, a second intermediate electrode, and a second electrode according to various disclosed embodiments of the present disclosure;

FIG. 21 illustrates another exemplary driving backplane according to various disclosed embodiments of the present disclosure;

FIG. 22 illustrates another exemplary driving backplane according to various disclosed embodiments of the present disclosure;

FIG. 23 illustrates another exemplary driving backplane according to various disclosed embodiments of the present disclosure;

FIG. 24 illustrates another exemplary display panel according to various disclosed embodiments of the present disclosure;

FIG. 25 illustrates another exemplary display module according to various disclosed embodiments of the present disclosure;

FIG. 26 illustrates a top view of a first base material and first signal line according to various disclosed embodiments of the present disclosure;

FIG. 27 illustrates another exemplary display module according to various disclosed embodiments of the present disclosure;

FIG. 28 illustrates another exemplary display module according to various disclosed embodiments of the present disclosure;

FIG. 29 illustrates another exemplary display module according to various disclosed embodiments of the present disclosure;

FIG. 30 illustrates another exemplary display module according to various disclosed embodiments of the present disclosure;

FIG. 31 illustrates another exemplary display module according to various disclosed embodiments of the present disclosure;

FIG. 32 illustrates another exemplary display module according to various disclosed embodiments of the present disclosure;

FIG. 33 illustrates another exemplary display module according to various disclosed embodiments of the present disclosure;

FIG. 34 illustrates another exemplary display module according to various disclosed embodiments of the present disclosure;

FIG. 35 illustrates another exemplary display module according to various disclosed embodiments of the present disclosure;

FIG. 36 illustrates another exemplary display module according to various disclosed embodiments of the present disclosure;

FIG. 37 illustrates another exemplary display module according to various disclosed embodiments of the present disclosure;

FIG. 38 illustrates another exemplary display module according to various disclosed embodiments of the present disclosure;

FIG. 39 illustrates another exemplary display module according to various disclosed embodiments of the present disclosure;

FIG. 40 illustrates another exemplary display module according to various disclosed embodiments of the present disclosure; and

FIG. 41 illustrates an exemplary display device according to various disclosed embodiments of the present disclosure.

### DETAILED DESCRIPTION

To better understand the technical solution of the present disclosure, the embodiments of the present disclosure are described in detail below in conjunction with the accompanying drawings.

It should be clear that the described embodiments are only part of the embodiments of the present disclosure, not all of the embodiments. Based on the embodiments of the present disclosure, all other embodiments obtained by ordinary technicians in the field without creative work belong to the scope of protection of the present disclosure.

The terms used in the embodiments of the present disclosure are only for the purpose of describing specific embodiments, and are not intended to limit the present disclosure. The singular forms of “a”, “said” and “the” used in the embodiments of the present disclosure and the appended claims are also intended to include plural forms, unless the context clearly indicates other meanings.

It should be understood that the term “and/or” used in this disclosure is only a description of the association relationship of the associated objects, indicating that there may be three relationships, for example, A and/or B may represent: A exists alone, A and B exist at the same time, and B exists alone. In addition, the character “/” in this disclosure generally indicates that the associated objects before and after are in an “or” relationship.

The present disclosure provides a display panel. The display panel may be a light-emitting diode (LED) display panel.

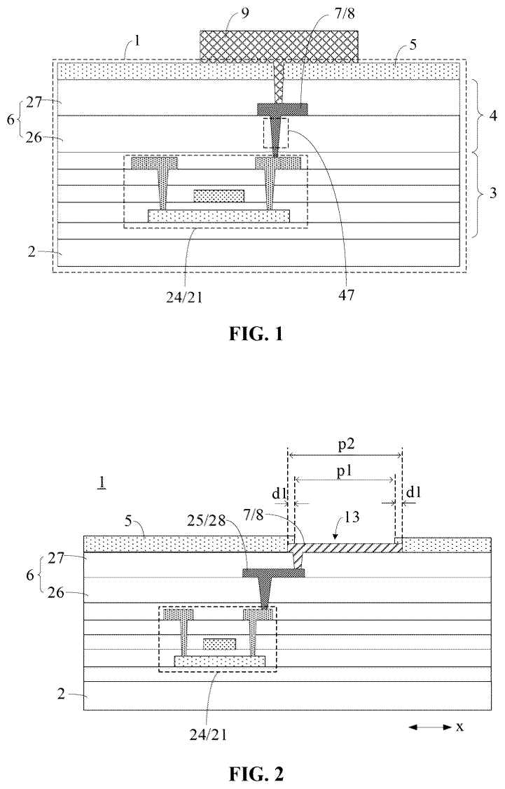

FIG. 1 illustrates a structural schematic diagram of an exemplary display panel according to various disclosed embodiments of the present disclosure. As shown in FIG. 1, the display panel may include a driving backplane 1. The driving backplane 1 may include a substrate 2, a circuit layer 3, a first film layer 4 located on a side of the circuit layer 3 away from the substrate 2, and a first inorganic protective layer 5 located on a side of the first film layer 4 away from the substrate 2.

The first film layer 4 may include a planarization layer 6 and a first electrode layer 7. The first electrode layer 7 may include a first electrode 8, and at least a portion of the first electrode layer 7 may be exposed by the first inorganic protective layer 5. The first electrode 8 may be configurated as a lead electrode of the driving backplane 1 to construct a signal connection between the driving backplane 1 and other external structures. For example, at least a portion of the first electrode 8 may be configured to transmit the signal transmitted by the internal circuit of the driving backplane 1 to the light-emitting element, and at least a portion of the first electrode 8 may be configured to transmit the signal provided by the driving structures, such as the driving chip and the printed circuit board, to the internal circuit of the driving backplane 1.

The display panel may also include a connection member 9 located on one side of the driving backplane 1. The connection member 9 may be electrically connected to the first electrode 8, which may be regarded as a bonding layer.

In the display panel provided in the embodiment of the present disclosure, the outermost insulation layer of the driving backplane 1 may include the first inorganic protective layer 5, and the first inorganic protective layer 5 may include an inorganic material. Compared with organic materials, the inorganic material may have better water and oxygen barrier properties, and thus the driving backplane 1 may have better water and oxygen barrier properties.

For example, in the period from the completion of the production of the driving backplane 1 to the formation of the connection member 9, the first inorganic protective layer 5 may effectively block the water and oxygen in the environment to prevent the water and oxygen in the environment from penetrating into the driving backplane 1. When the connection member 9 is subsequently formed using an etching solution or other solution, the first inorganic protective layer 5 may also effectively block the water and oxygen in the solution to prevent the water and oxygen in the solution from penetrating into the driving backplane 1. This may effectively improve the water and oxygen resistance of the driving backplane 1, reduce the risk of oxidation of the first electrode 8, and improve the connection reliability of the first electrode 8.

In addition, there are currently a variety of processes for forming the connection member 9. If the connection member 9 is formed by a chemical plating process, when forming the connection member 9, copper may need to be formed first as a seed layer substrate, and a stripping solution may be needed when forming the copper substrate. The stripping solution may generally include an amine material. If the outermost insulation layer of the driving backplane 1 is an organic layer, when the stripping liquid contacts the organic layer, the organic material and the amine material may have drug resistance problems, and the two materials may react, resulting in film peeling, causing product defects and reliability risks. In the present disclosure, the outermost insulation layer of the driving backplane 1 may be an inorganic layer. The inorganic material may not have drug resistance problems with the amine material, and may also separate the organic layer from the stripping liquid, preventing the stripping liquid from penetrating into the organic layer, thereby avoiding the stripping liquid from contacting the organic layer and reacting, effectively solving the film peeling problem caused by material drug resistance problems in the process of the connection member 9.

In one embodiment, the first electrode layer 7 may include an anti-oxidation metal material, for example, a titanium material. Exemplarily, in one structure, the first electrode layer 7 may be a titanium-aluminum-titanium structure, that is, including a stacked first titanium layer, an aluminum layer, and a second titanium layer.

When the first electrode layer 7 includes an anti-oxidation metal material, the first electrode layer 7 itself may have a desired anti-oxidation property, and the first electrode 8 may not need to rely entirely on the protection of the first inorganic protective layer 5. Even if the first electrode 8 is exposed by the first inorganic protective layer 5, the exposed portion may not be oxidized.

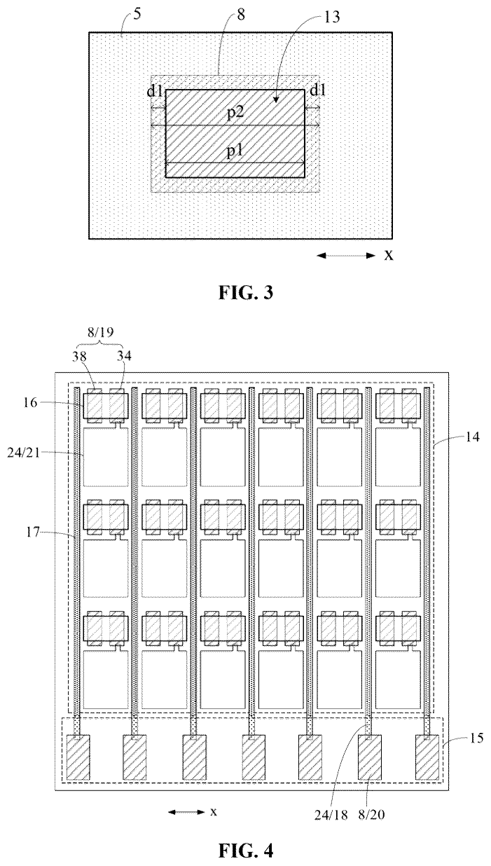

FIG. 2 is a schematic diagram of the structure of an exemplary driving backplane 1 according to various disclosed embodiments of the present disclosure, and FIG. 3 is a top view of the first inorganic protective layer 5, the first electrode 8 and the first connection hole 13 according to various disclosed embodiment of the present disclosure. In one embodiment, as shown in FIGS. 2-3, the first electrode layer 7 may be located between the planarization layer 6 and the first inorganic protective layer 5.

The first inorganic protective layer 5 may include a first connection hole 13 that may expose the first electrode 8. Moreover, in a direction perpendicular to the plane where the substrate 2 is located, the projection of the edge of the first connection hole 13 may be located within the projection of the first electrode 8. For example, for the overlapping first electrode 8 and the first connection hole 13, along the first direction x, the width p1 of the first connection hole 13 in the first direction x may be less than the width p2 of the first electrode 8 in the first direction x. The first direction x may be parallel to the plane where the substrate 2 is located, for example, it may be the arrangement direction of the two relative outer edges in the display panel.

In the above structure, the first inorganic protective layer 5 may cover the outer portion of the first electrode 8, which may prevent water and oxygen from corroding the side surface of the first electrode 8. In particular, when the first electrode 8 is a titanium-aluminium-titanium structure, the side surface of the aluminum layer may not be covered with titanium material. At this time, the first inorganic protective layer 5 may be used to protect the side surface of the aluminum layer to prevent its side surface from being exposed and corroded by water and oxygen.

Further, along the first direction x, the distance d1 between the edge of the first connection hole 13 and the edge of the first electrode 8 may be greater than approximately 3.5 μm. This distance range may cover the process error accuracy of the first connection hole 13 and the first electrode 8. In an actual process, even if the actual positions of the two are deviated due to factors such as process errors, etc., it may still be ensured that the first inorganic protective layer 5 may cover the side surface of the first electrode 8.

As mentioned above, in the embodiment of the present disclosure, the first electrode 8 may be used as a lead-out electrode for constructing a signal connection between the driving backplane 1 and the light-emitting element, and for constructing a signal connection between the driving backplane 1 and a driving structure, such as a driving chip and a printed circuit board. In this regard, the details may be referred to FIGS. 4-6.

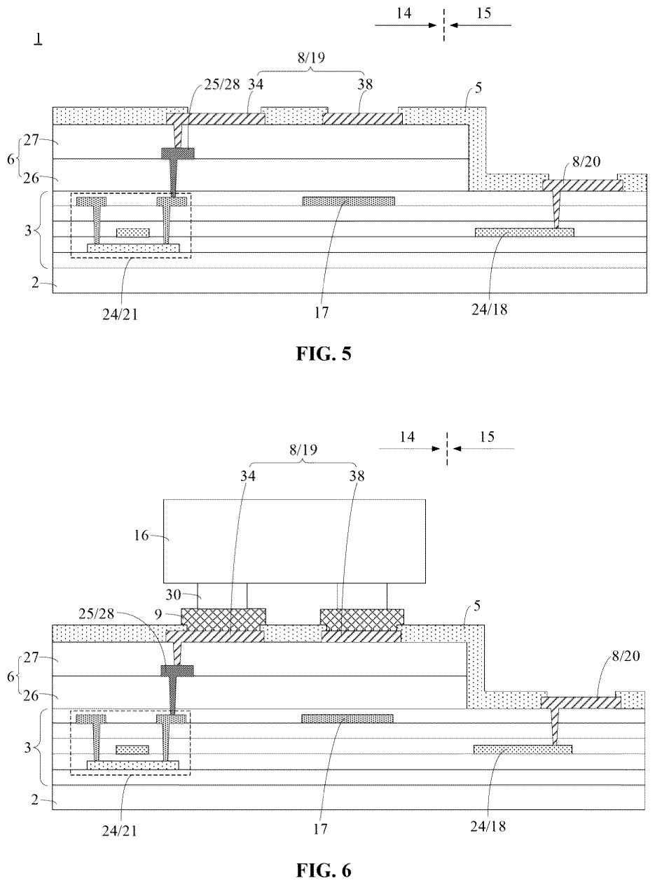

FIG. 4 is a top view of the driving backplane 1 provided in an embodiment of the present disclosure, FIG. 5 is another structural schematic diagram of the driving backplane 1 provided in an embodiment of the present disclosure, and FIG. 6 is another structural schematic diagram of the display panel provided in an embodiment of the present disclosure. As shown in FIGS. 4-6, the display panel may include a display area 14 and a first non-display area 15. The first non-display area 15 may be a non-display area corresponding to the lower frame.

The display area 14 may include a light-emitting element 16 and a first signal line 17. The light-emitting element 16 may be an LED, such as a Micro LED or a Mini LED, etc. The first signal line 17 may include various display signal lines such as a data line, a reset line, and a power line. The first non-display area 15 may include a connection signal line 18 electrically connected to the first signal line 17. Moreover, at least a portion of the first signal line 17 and/or at least a portion of the connection signal line 18 may be located in the circuit layer 3.

The first electrode 8 may include a first sub-electrode 19 and a second sub-electrode 20. The first sub-electrode 19 may be located in the display area 14 and may be electrically connected to the electrode 30 of the light-emitting element 16, and may be used to transmit the signal transmitted by the metal line inside the driving backplane 1 to the electrode 30 of the light-emitting element 16, so as to drive the light-emitting element 16 to emit light normally. Further, the first sub-electrode 19 may be bonded to the electrode of the light-emitting element 16 through the connection member 9, and the specific structure may be described in detail in the subsequent embodiments.

The second sub-electrode 20 may be located in the first non-display area 15 and may be electrically connected to the connection signal line 18, and may be used to transmit the signal provided by the driving structure such as the driving chip and the printed circuit board to the connection signal line 18. Further, the second sub-electrode 20 may be bonded to the pin of the driving structure through the connection member 9, or it may be electrically connected to the driving structure without connecting the connection member 9, and the specific structure will be described in detail in the subsequent embodiments. After introducing the first sub-electrode 19 and the second sub-electrode 20 here, they will not be repeatedly introduced when they are involved later.

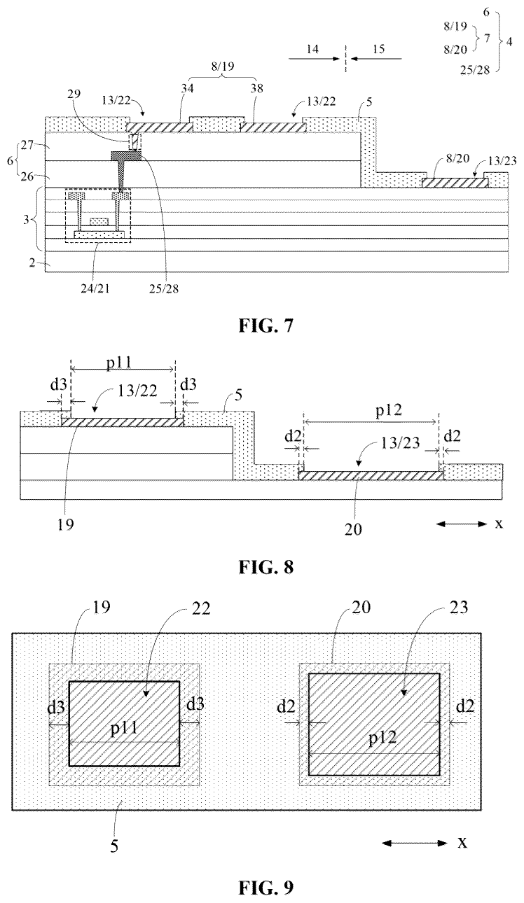

FIG. 7 is another structural schematic diagram of the driving backplane 1 provided in an embodiment of the present disclosure. In one embodiment, as shown in FIG. 7, the first connection hole 13 may include a first via hole 22 exposing the first sub-electrode 19 such that the first inorganic protective layer 5 may be used to design the first sub-electrode 19 to be edge-wrapped, and the side surface of the first sub-electrode 19 may be protected. In another embodiment, the first connection hole 13 may include a second via hole 23 exposing the second sub-electrode 20 such that the first inorganic protective layer 5 may be used to design the second sub-electrode 20 to be edge-wrapped, and the side surface of the second sub-electrode 20 may be protected.

FIG. 8 is a schematic diagram of a size comparison of the first via hole 22 and the second via hole 23 provided in an embodiment of the present disclosure, and FIG. 9 is a top view of the first inorganic protective layer 5, the first sub-electrode 19, the second sub-electrode 20, the first via hole 22 and the second via hole 23 provided in an embodiment of the present disclosure. As shown in FIG. 8 and FIG. 9, when the first connection hole 13 includes both the first via hole 22 and the second via hole 23, along the first direction x, the distance d2 between the edge of the second via hole 23 and the edge of the second sub-electrode 20 may be less than the distance d3 between the edge of the first via hole 22 and the edge of the first sub-electrode 19. Generally, the width of the second sub-electrode 20 in the first direction x may be greater than or equal to the width of the first sub-electrode 19 in the first direction X, and when d2 is less than d3, it may mean that the width p12 of the second via hole 23 in the first direction x may be greater than the width p11 of the first via hole 22 in the first direction x.

Under the condition that d2<d3 is satisfied, in one configuration, the condition that d2>3.5 μm and d3>4 μm may be set.

According to the above introduction to the second sub-electrode 20, the second sub-electrode 20 may be used to write various driving signals provided by the driving structure into the signal line of the display panel. Thus, the connection stability of the second sub-electrode 20 may greatly affect the display performance of the display panel.

When the first inorganic protective layer 5 is designed to wrap the first sub-electrode 19 and the second sub-electrode 20, based on the above design, the first inorganic protective layer 5 may cover the outer portion of the second sub-electrode 20 to a smaller extent, such that a larger area of the second sub-electrode 20 may be exposed to the outer surface of the driving backplane 1, which may be convenient for increasing the contact area between the second sub-electrode 20 and the connection member 9, the side wiring, etc., and may help to improve the connection stability of the second sub-electrode 20.

Further, regarding the size of d2, different designs may be made according to the application of the display panel. The display panel provided in the embodiments of the present disclosure may be used in conventional display products such as mobile phones and computers, and may also be used in spliced display products such as outdoor large screens, etc. When the display panel is used in a conventional non-spliced display product, the display panel may not have too high requirements for the width of the lower frame, thus the size of the second sub-electrode 20 may be set larger, then d2 may also be set slightly larger under the condition that the second sub-electrode 20 may expose a sufficient area. For example, d2 corresponding to this type of display panel may be set to be greater than approximately 5 μm.

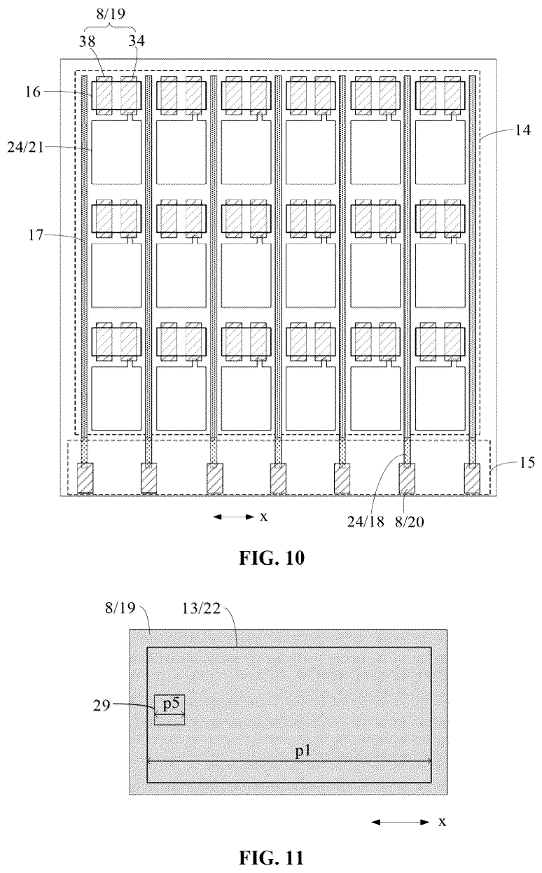

FIG. 10 is another top view of the driving backplane provided by an embodiment of the present disclosure. As shown in FIG. 10, when the display panel is used in a spliced display product, to weaken the visual seam, the lower frame of the display panel may need to be as narrow as possible. In this structure, the size of the second sub-electrode 20 may be set smaller, and the second sub-electrode 20 may be closer to the outer edge of the display panel. Then, under the condition that the second sub-electrode 20 may expose a sufficient area, d2 may be relatively small. For example, d2 corresponding to this type of display panel may be set to be greater than approximately 3.5 μm.

In one embodiment, referring to FIG. 7, the circuit layer 3 may include a first structure 24, the first film layer 4 may also include a second electrode layer 25, and the planarization layer 6 may include a first planarization layer 26 and a second planarization layer 27. The first planarization layer 26 may be located between the second electrode layer 25 and the circuit layer 3, and the second planarization layer 27 may be located between the first electrode layer 7 and the second electrode layer 25.

The second electrode layer 25 may include an intermediate electrode 28. At least a portion of the first electrode 8 may be electrically connected to the first structure 24 through the intermediate electrode 28.

As mentioned above, the lead-out electrode in the embodiment of the present disclosure may include an anti-oxidation metal material. Therefore, compared with the existing lead-out electrode, the lead-out electrode in the present disclosure itself may have better anti-oxidation performance. In the above structure, the present disclosure uses an additional anti-oxidation metal layer to form the lead-out electrode, and the original lead-out electrode may be used as the intermediate electrode 28 between the new lead-out electrode and the first structure 24.

In the prior art, there are many wirings in the metal layer where the lead-out electrode is located. In addition to setting the lead-out electrode, the metal layer also needs to set some other metal wirings, such as a positive power supply line, which leads to a limited size of the lead-out electrode. Correspondingly, the area of the lead-out electrode exposed by the via hole may also be very small.

The embodiment of the present disclosure may use an additional anti-oxidation metal layer to form the lead-out electrode (the first electrode 8), which may provide a larger wiring space for the lead-out electrode, thus the size of the lead-out electrode may be made larger. After the size of the lead-out electrode is increased, it may be more convenient to open a larger connection hole in the first inorganic protective layer 5 such that the lead-out electrode may be exposed in a larger area for subsequent contact and connection with the connection member 9, side wirings and other structures.

In addition, in the embodiment of the present disclosure, the first inorganic protective layer 5 and the first electrode layer 7 above the second electrode layer 25 may both block water and oxygen to prevent water and oxygen from penetrating into the second electrode layer 25. Thus, the intermediate electrode 28 in the embodiment of the present disclosure may not be easy to oxidize.

For the first planarization layer 26 and the second planarization layer 27 involved in the embodiment of the present disclosure, the film thickness of the two planarization layers may be set to be equal. However, it can be understood that at the position where the two overlap with the intermediate electrode 28, the film thickness of the second planarization layer 27 above the intermediate electrode 28 may be slightly smaller than the film thickness of the first planarization layer 26 below the intermediate electrode 28.

Further, referring to FIG. 7, the area of the orthographic projection of the first electrode 8 on the substrate 2 may be greater than the area of the orthographic projection of the intermediate electrode 28 connected thereto on the substrate 2. Accordingly, compared with the related art, the area of the lead-out electrode may be further increased.

In another embodiment, referring to FIG. 7, the first inorganic protective layer 5 may include a first connection hole 13 exposing the first electrode 8, and at least a portion of the first electrode 8 may also be electrically connected to the intermediate electrode 28 through a second connection hole 29 penetrating the second planarization layer 27. The aperture of the first connection hole 13 may be larger than the aperture of the second connection hole 29 such that the first electrode 8 may expose a sufficient area in the first connection hole 13.

FIG. 11 is a top view of the first electrode 8, the first connection hole 13 and the second connection hole 29 provided in an embodiment of the present disclosure. As shown in FIG. 11, along the first direction x, the width p1 of the first connection hole 13 may be larger than the width p5 of the second connection hole 29.

It should be noted that in actual situations, the apertures of the via holes at different positions may be unequal. For example, the closer to the substrate, the narrower the via hole may be, and the smaller the aperture may be. The comparison between the apertures of the two via holes described in the embodiment of the present disclosure may be understood as the comparison between the apertures of the two via holes at the same cross-section, or it may also be understood as the comparison between the apertures of the two via holes at the opening position. The widths of the via holes may be similar, and will not be repeated herein.

FIG. 12 is another structural schematic diagram of the display panel provided in an embodiment of the present disclosure. As shown in FIG. 12, in one embodiment, the first inorganic protective layer 5 may include a first connection hole 13 exposing the first electrode 8. The first connection hole 13 may include a first via hole 22 exposing the first sub-electrode 19.

The area of the orthographic projection of the first via hole 22 on the substrate 2 may be larger than the area of the orthographic projection of the electrode 30 of the light-emitting element 16 connected thereto on the substrate 2. That is, along the first direction x, the width p11 of the first via hole 22 may be larger than the width p6 of the electrode 30 of the light-emitting element 16.

When the first inorganic protective layer 5 is designed to wrap the first sub-electrode 19, the portion of the connection member 9 in the first via hole 22 may not be uneven due to the step difference of the first inorganic protective layer 5 at the edge of the first via hole 22. The width of the first via hole 22 may be set to be larger than the width of the electrode 30 of the light-emitting element 16. When the light-emitting element 16 is bonded, the electrode 30 of the light-emitting element 16 may be placed in the area corresponding to the first via hole 22, such that the light-emitting element 16 is bonded to this flatter portion of the connection member 9, and the stability of the light-emitting element 16 may be better.

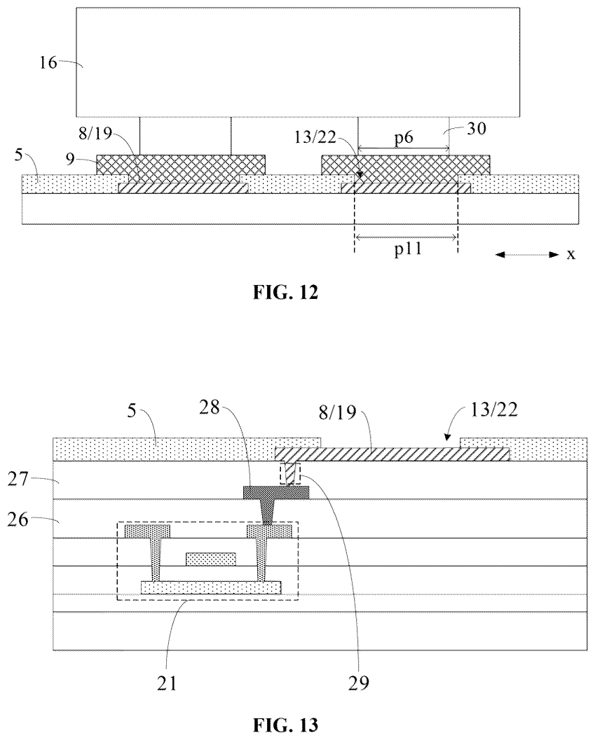

FIG. 13 is another structural schematic diagram of the display panel provided by the embodiment of the present disclosure. Regarding the relative positional relationship between the first connection hole 13 and the second connection hole 29, in one embodiment, as shown in FIG. 13, for the first connection hole 13 and the second connection hole 29 overlapping with the same first electrode 8, the second connection hole 29 may not overlap with the first connection hole 13. At this time, the second connection hole 29 may be further covered by the first inorganic protective layer 5, and at the location of the second connection hole 29, the first inorganic protective layer 5 and the first electrode 8 may be used to block water and oxygen at the same time, thereby reducing the risk of water and oxygen penetrating through the second connection hole 29 to a greater extent.

FIG. 14 is another top view of the first sub-electrode 19, the first connection hole 13 and the second connection hole 29 corresponding to FIG. 13. As shown in FIG. 14, the first electrode 8 may include a first side 31 and a second side 32 opposite to each other.

For the first connection hole 13 and the second connection hole 29 overlapping the same first electrode 8, along the first direction x, the distance d4 between the first connection hole 13 and the first edge 31 and the distance d5 between the first connection hole 13 and the second edge 32 may be equal. Moreover, the orthographic projection of the second connection hole 29 on the substrate 2 may be located between the orthographic projection of the first connection hole 13 on the substrate 2 and the orthographic projection of the first edge 31 on the substrate 2.

When the first connection hole 13 and the second connection hole 29 are required to be staggered, in this arrangement, along the first direction x, the first connection hole 13 may be centred relative to the first electrode 8, and the second connection hole 29 may be located between the first connection hole 13 and the first edge 31. At this time, the first inorganic protective layer 5 may have the same degree of hemming on both sides of the first electrode 8.

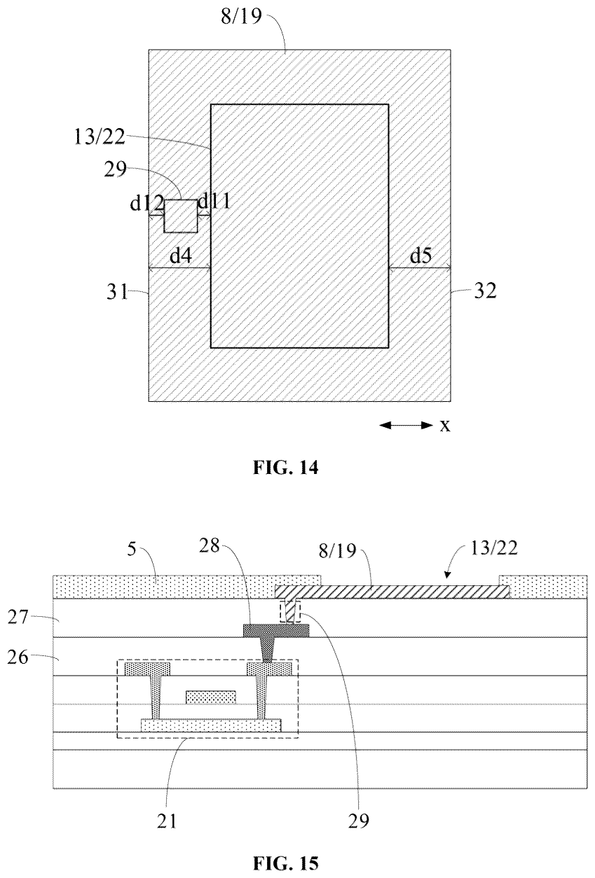

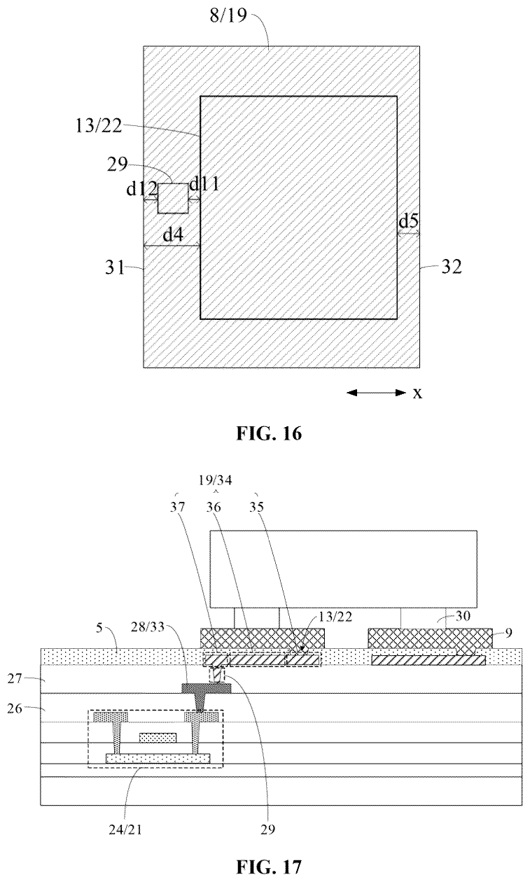

FIG. 15 is another structural schematic diagram of a display panel provided in an embodiment of the present disclosure, and FIG. 16 is another top view of the first sub-electrode 19, the first connection hole 13 and the second connection hole 29 corresponding to FIG. 15. As shown in FIGS. 15-16, in some embodiments, the first electrode 8 may include a first edge 31 and a second edge 32 opposite to each other.

For the first connection hole 13 and the second connection hole 29 overlapping the same first electrode 8, along the first direction x, the distance d4 between the first connection hole 13 and the first edge 31 may be greater than the distance d5 between the first connection hole 13 and the second edge 32, and the distance between the second connection hole 29 and the first edge 31 may be less than the distance between the second connection hole 29 and the second edge 32. The first direction x may be parallel to the plane where the substrate 2 is located.

When the first connection hole 13 and the second connection hole 29 are required to be staggered, under this arrangement, the first inorganic protective layer 5 may cover more first electrode 8 on the side where the second connection hole 29 is located, such that the edge of the first connection hole 13 on this side may not overlap with the second connection hole 29, and on the side away from the second connection hole 29, only a smaller area of the first electrode 8 may be covered. Accordingly, the edge of the first connection hole 13 on this side may be expanded as much as possible, so as to increase the area of the first electrode 8 exposed by the first connection hole 13 as much as possible.

FIG. 17 is another structural schematic diagram of a display panel provided in an embodiment of the present disclosure. As shown in FIG. 17, the first structure 24 may include a pixel circuit 21. The middle electrode 28 may include a first middle electrode 33 electrically connected to the pixel circuit 21.

For the first sub-electrode 19 included in the first electrode 8 for electrically connecting to the light-emitting element 16, the first sub-electrode 19 may include a first type of first sub-electrode 34. The first type of first sub-electrode 34 may also be electrically connected to the first middle electrode 33 through the second connection hole 29 penetrating the second planarization layer 27. For example, the first type of first sub-electrode 34 may include the first sub-electrode 19 connected to the positive electrode of the light-emitting element 16.

The first type of first sub-electrode 34 may include a first portion 35, a second portion 36 and a third portion 37. The second portion 36 may be located between the first portion 35 and the third portion 37. In the direction perpendicular to the plane where the substrate 2 is located, the first portion 35 may overlap with the first connection hole 13, the third portion 37 may overlap with the second connection hole 29, and the second portion 36 may overlap with the electrode 30 of the light-emitting element 16.

The second portion 36 may be the middle portion of the first type of first sub-electrodes 34. Since the second portion 36 may not overlap with the first connection hole 13 and the second connection hole 29, the second portion 36 may be relatively flatter, and accordingly, the connection member 9 above the second portion 36 may also be flatter. When the light-emitting element 16 is subsequently bonded, the stability of the light-emitting element 16 may be improved by allowing the positive electrode of the light-emitting element 16 to fall within the area where the second portion 36 is located.

In one embodiment of the present disclosure, the overlap between the first type of first sub-electrode 34 and the pixel circuit 21 may be related to the overlap between the light-emitting element 16 and the pixel circuit 21. For example, in the direction perpendicular to the plane where the substrate is located, when the light-emitting element 16 and the pixel circuit 21 do not overlap, the first type of first sub-electrodes 34 and the pixel circuit 21 may not overlap. In some embodiments, in the direction perpendicular to the plane where the substrate is located, when the light-emitting element 16 overlaps with the pixel circuit 21, the first type of first sub-electrodes 34 and the pixel circuit 21 may also overlap.

In some embodiments, referring to FIG. 14-16, for the first connection hole 13 and the second connection hole 29 overlapping the same first electrode 8, to ensure that the first connection hole 13 and the second connection hole 29 may be staggered by a sufficient distance, the distance d11 between the first connection hole 13 and the second connection hole 29 along the first direction x may be set to be greater than approximately 3.5 μm.

In addition, to ensure the connection reliability between the first electrode 8 and the intermediate electrode 28, the outer edge of the first electrode 8 and the second connection hole 29 may need to be spaced a sufficient distance apart. In this regard, referring to FIG. 14 and FIG. 16 again, along the first direction x, the distance d12 between the first edge 31 of the first electrode 8 and the second connection hole 29 may also be set to be greater than approximately 3.5 μm.

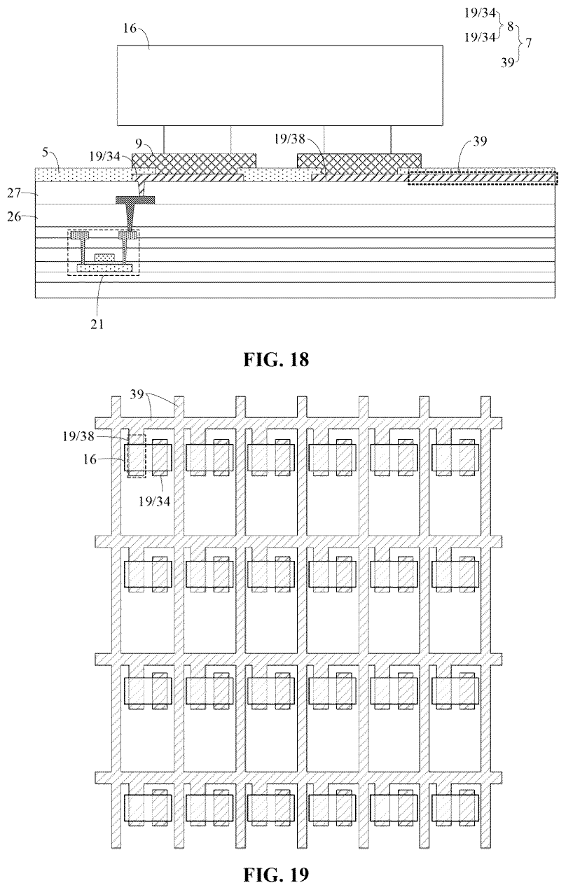

FIG. 18 is another structural schematic diagram of the display panel provided in an embodiment of the present disclosure, and FIG. 19 is a top view of the first electrode 8 and the first power line 39 provided in an embodiment of the present disclosure. As shown in FIG. 18 and FIG. 19, in one embodiment, for the first sub-electrode 19 included in the first electrode 8 for electrically connecting to the light-emitting element 16, the first sub-electrode 19 may also include a second type of first sub-electrode 38, and the second type of first sub-electrode 38 may also be electrically connected to the first power line 39. The first power line 39 may be configured to provide a negative power signal, that is, the second type of first sub-electrode 38 may be the first sub-electrode 19 connected to the negative electrode of the light-emitting element 16.

The first power line 39 may be located in the first electrode layer 7. In one embodiment, the first power line 39 may be a grid-like structure to achieve a smaller load. When a single anti-oxidation metal layer is used as the first electrode layer 7, the anti-oxidation metal layer may be used to further form the first power line 39.

Compared with setting the first power line 39 in the circuit layer 3, the first power line 39 may be located in the first electrode layer 7, and the second type of first sub-electrode 38 may be directly connected to the first power line 39 to realize the electrical connection between the two. The second type of first sub-electrode 38 may not need to be connected to the first power line 39 through a via hole, and the connection may be simpler. Moreover, the first power line 39 may not need to occupy space with the original metal wiring in the circuit layer 3.

Compared with setting the first power line 39 in the same layer as a metal layer in the connecting part 9, the first power line 39 may be located in the first electrode layer 7, which may avoid limiting the optional process of the connection member 9. For example, the selection of the material of the connection member 9 may not need to consider the first power line 39. In one process route, the connection member 9 may be formed by a chemical plating process. In another process route, the connection member 9 may be formed by an evaporation process. In addition, the first power line 39 may not occupy the setting space of the connection member 9, and the size of the connection member 9 may also be set to be larger.

In addition, since the first electrode layer 7 may be formed of an anti-oxidation metal material, the first power line 39 may be formed on the first electrode layer 7, and the first power line 39 itself may have a better anti-oxidation performance, and it may not be easy to be oxidized. Moreover, the first inorganic protective layer 5 may cover the first power line 39 to further protect the first power line 39.

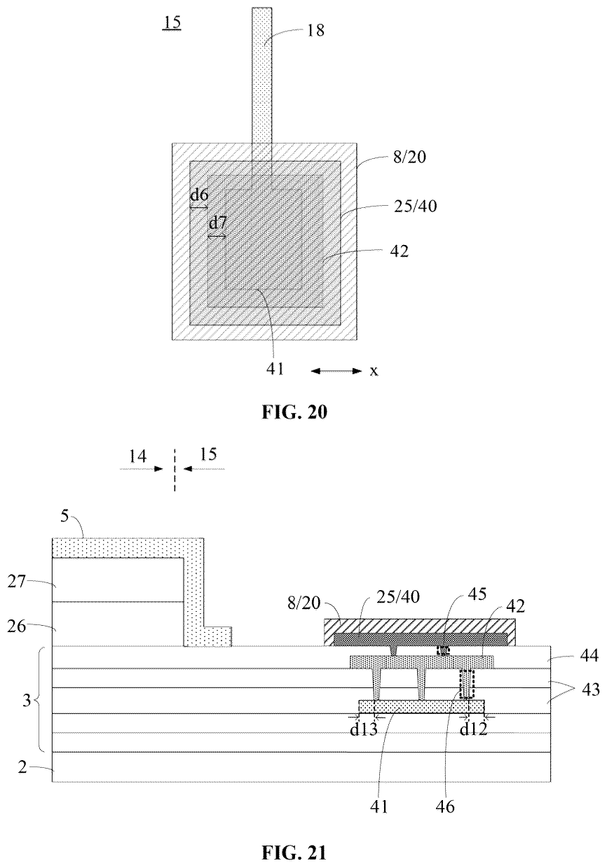

FIG. 20 is a top view of the connection signal line 18, the first connection electrode 41, the second connection electrode, the second intermediate electrode 40, and the second sub-electrode 20 provided in an embodiment of the present disclosure, and FIG. 21 is another structural schematic diagram of the driving backplane 1 provided in an embodiment of the present disclosure. In one embodiment, as shown in FIG. 20 and FIG. 21, the intermediate electrode 28 may include a second intermediate electrode 40 located in the first non-display area 15. For the second sub-electrode 20 included in the first electrode 8 for electrically connecting to the driving structure, the second sub-electrode 20 may be electrically connected to the connection signal line 18 through the second intermediate electrode 40. The edge of the second planarization layer 27 may be located on the side of the second sub-electrode 20 adjacent to the display area 14, and the second sub-electrode 20 may cover the second intermediate electrode 40.

The connection reliability of the second sub-electrode 20 in the first non-display area 15 may need more attention. Therefore, the second planarization layer 27 between the second intermediate electrode 40 and the second sub-electrode 20 may be removed such that the second sub-electrode 20 may be directly connected to the second intermediate electrode 40, which may enhance the connection stability between the two.

In addition, in this structure, although the first inorganic protective layer 5 may not be provided above the second intermediate electrode 40, because the second sub-electrode 20 may include an anti-oxidation metal material and may have good anti-oxidation performance, the second intermediate electrode 40 may still be protected by the second sub-electrode 20 to prevent the second intermediate electrode 40 from being oxidized by covering the second intermediate electrode 40 with the second sub-electrode 20. Further, referring to FIG. 21, the second sub-electrode 20 may also cover the side wall of the second intermediate electrode 40 to continue to protect the second intermediate electrode 40 in all directions.

In another embodiment, referring to FIG. 20 and FIG. 21, the intermediate electrode 28 may include the second intermediate electrode 40 located in the first non-display area 15. For the second sub-electrode 20 included in the first electrode 8 for electrically connecting to the driving structure, the second sub-electrode 20 may be electrically connected to the connection signal line 18 through the second intermediate electrode 40.

The circuit layer 3 may also include a first connection electrode 41 and a second connection electrode 42. One or at least two first inorganic insulating layers 43 may be included between the first connection electrode 41 and the second connection electrode 42, and one or at least two second inorganic insulation layers 44 may be included between the second connection electrode 42 and the second intermediate electrode 40.

The second intermediate electrode 40 may be electrically connected to the second connection electrode 42 through at least two third connection holes 45 penetrating the second inorganic insulation layer 44, and the second connection electrode 42 may be electrically connected to the first connection electrode 41 through at least two fourth connection holes 46 penetrating the first inorganic insulation layer 43.

The connection signal line 18 may be electrically connected to the first connection electrode 41 and/or the second connection electrode 42. The accompanying drawings of the embodiment of the present disclosure are schematically illustrated by taking the connection signal line 18 and the first connection electrode 41 in the same layer as an example.

The above structure uses the first connection electrode 41 and the second connection electrode 42 to act as auxiliary connection electrodes between the second intermediate electrode 40 and the connection signal line 18. Exemplarily, when the connection signal line 18 and the first connection electrode 41 are in the same layer, the connection signal line 18 may be connected with the first connection electrode 41 and connected to the second intermediate electrode 40 through the second connection electrode 42. Such a setting may reduce the load and signal attenuation on the one hand, and may also facilitate the connection between the connection signal line 18 and the second intermediate electrode 40 when the metal layer is far apart in the longitudinal direction, and reduce the depth of the via hole during connection.

Moreover, the second intermediate electrode 40 and the second connection electrode 42, and the second connection electrode 42 and the first connection electrode 41 may not directly contacted and connected, but the inorganic insulation layer between these electrodes may be retained such that this portion of the inorganic insulation layer may be used to isolate water and oxygen. In addition, the second intermediate electrode 40 and the second connection electrode 42, and the second connection electrode 42 and the first connection electrode 41 may be connected through at least two via holes, respectively, which may also reduce the contact resistance.

Further, referring to FIG. 21, in a direction perpendicular to the plane where the substrate 2 is located, the third connection hole 45 may not overlap with the fourth connection hole 46, thereby further blocking the penetration of water and oxygen in the direction perpendicular to the plane where the substrate 2 is located.

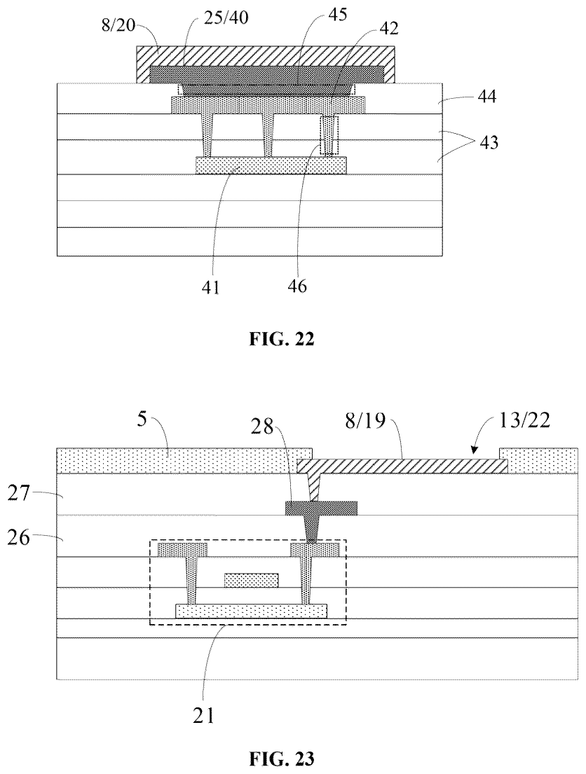

FIG. 22 is another structural schematic diagram of the driving backplane 1 provided by an embodiment of the present disclosure. As shown in FIG. 22, in other embodiments, the second intermediate electrode 40 may also be electrically connected to the second connection electrode 42 through a third connection hole 45 penetrating the second inorganic insulation layer 44, and the second connection electrode 42 may be electrically connected to the second connection electrode 42 and the first connection electrode 41 through at least two fourth connection holes 46 penetrating the first inorganic insulating layer 43. Moreover, the third connection hole 45 may cover at least two fourth connection holes 46.

Under this structure, the second intermediate electrode 40 and the second connection electrode 42 may be connected only through a third connection hole 45 with a large aperture, which may help to reduce the contact resistance between the second intermediate electrode 40 and the second connection electrode 42.

In one embodiment of the present disclosure, referring to FIG. 21, in the third connection hole 45 and the fourth connection hole 46, along the first direction x, the distance d12 between the third connection hole 45 or the fourth connection hole 46 adjacent to the outer edge of the display panel and the edge of the first connection electrode 41 may be greater than approximately 5 μm, and the distance d13 between the third connection hole 45 or the fourth connection hole 46 adjacent to the display area 14 and the edge of the first connection electrode 41 may be greater than approximately 5 μm.

In another embodiment, in combination with FIG. 20 and FIG. 21, in a direction perpendicular to the plane where the substrate 2 is located, the second intermediate electrode 40 may cover the second connection electrode 42, and, along the first direction x, there may be a gap between the edge of the second intermediate electrode 40 and the edge of the second connection electrode 42. For example, in the first direction x, the distance d6 between the edge of the second intermediate electrode 40 and the edge of the second connection electrode 42 may be greater than approximately 2 μm.

In a direction perpendicular to the plane where the substrate 2 is located, the second connection electrode 42 may cover the first connection electrode 41 and, along the first direction x, there may be a gap between the projection of the edge of the second connection electrode 42 and the projection of the edge of the first connection electrode 41. For example, in the first direction x, the distance d7 between the edge of the second connection electrode 42 and the edge of the first connection electrode 41 may be greater than approximately 2 μm.

In the above structure, in the direction away from the substrate 2, the first connection electrode 41, the second connection electrode 42 and the second intermediate electrode 40 may expand outward layer by layer, one may be to facilitate connection, and the other may be that the upper metal may cover the lower metal, and the upper metal may be used to block more water and oxygen to a certain extent.

In one embodiment, referring to FIG. 13, the first inorganic protective layer 5 may include a first connection hole 13 exposing the first electrode 8. In the direction perpendicular to the plane where the substrate 2 is located, for the first connection hole 13 and the intermediate electrode 28 overlapping with the same first electrode 8, at least a portion of the first connection hole 13 may not overlap with the intermediate electrode 28. In this way, the position of the first connection hole 13 may avoid the intermediate electrode 28 such that the first inorganic protective layer 5 may be covered above the intermediate electrode 28, avoiding water and oxygen from penetrating into the intermediate electrode 28 from above the intermediate electrode 28, and preventing the intermediate electrode 28 from oxidizing.

FIG. 23 is another structural schematic diagram of the driving backplane 1 provided by an embodiment of the present disclosure. As shown in FIG. 23, in other embodiments of the present disclosure, as shown in FIG. 23, in the direction perpendicular to the plane where the substrate 2 is located, for the first connection hole 13 and the intermediate electrode 28 overlapping with the same first electrode 8, at least a portion of the first connection hole 13 may also overlap with the intermediate electrode 28. This structure may be more suitable for display panels with high pixel density and small pixel pitch. Under the condition of limited layout space, the area of the first electrode 8 exposed by the first connection hole 13 may be increased as much as possible.

When the first electrode layer 7 includes an anti-oxidation metal material, in one embodiment, an additional anti-oxidation metal layer may not be added, but the material of the metal layer where the original lead-out electrode is located may be changed. Specifically, referring to FIG. 1, the circuit layer 3 may include a first structure 24. The first film layer 4 may include a first planarization layer 26, the first planarization layer 26 may be located between the first electrode layer 7 and the circuit layer 3, and at least a portion of the first electrode 8 may be electrically connected to the first structure 24 through a fifth connection hole 47 penetrating the first planarization layer 26. More specifically, only one first planarization layer 26 may be included between the first electrode layer 7 and the circuit layer 3.

This solution may change the forming material of the original electrode layer, for example, changing it from a molybdenum-aluminum-molybdenum structure to a titanium-aluminum-titanium structure, such that it may have good anti-oxidation performance. This solution may not require a new metal layer as the first electrode layer 7, and accordingly, there may be no need to add an additional process for the first electrode layer 7, which may simplify the film structure and the process flow of the display panel, and the panel structure may be thinner.

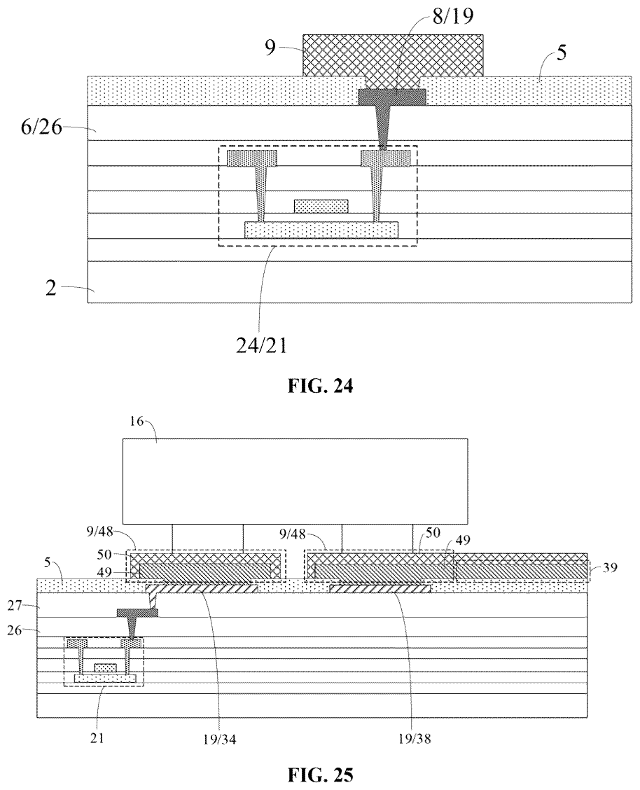

FIG. 24 is another structural schematic diagram of a display panel provided by an embodiment of the present invention. As shown in FIG. 24, the surface of the first inorganic protective layer 5 facing the substrate 2 may be in contact with the surface of the first planarization layer 26 away from the substrate 2. For example, there may be no other film layer between the first electrode layer 7 and the first inorganic protective layer 5, and the overall thickness of the display panel may be smaller.

In another embodiment, referring to FIG. 1, the first film layer 4 may also include a second planarization layer 27. The second planarization layer 27 may be located on the side of the first electrode layer 7 away from the substrate 2, and the first inorganic protective layer 5 may be located on the side of the second planarization layer 27 away from the substrate 2.

In this structure, after forming the first electrode layer 7, the second planarization layer 27 may be first formed, and then the first inorganic protective layer 5 may be formed. In this way, the first electrode layer 7 may be covered with a planarization layer, and the overall flatness of the driving backplane 1 may be better. When the connection member 9 is subsequently formed, the film flatness of the connection member 9 may also be better.

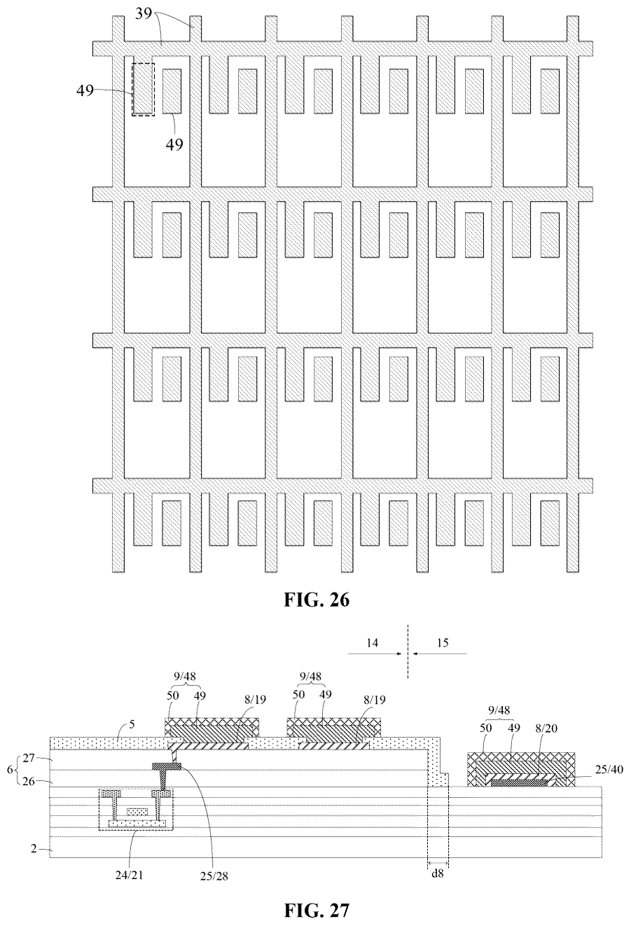

FIG. 25 is another structural schematic diagram of the display module provided by an embodiment of the present disclosure, and FIG. 26 is a top view of the first substrate 49 and the first signal line 17 provided by an embodiment of the present disclosure. As shown in FIGS. 25-26, in one embodiment, the connection member 9 may include a first connection member 48. The first connection member 48 may include a first substrate 49 and a first connection metal 50 covering the first substrate 49.

This first connection member 48 may be formed by a chemical plating process. The first substrate 49 may be used as a seed layer substrate and may include a copper material. The first connection metal 50 may be a metal grown on the surface of the substrate and may include a nickel layer and a gold layer.

For the first sub-electrode 19 included in the first electrode 8 for electrically connecting to the light-emitting element 16, the first sub-electrode 19 may include a second type of first sub-electrode 38, and the second type of first sub-electrode 38 may also be electrically connected to the first power line 39, and the first power line 39 may be used to provide a negative power supply voltage. The first power line 39 may be arranged in the same layer as the first substrate 49, and the first substrate 49 connected to the second type of first sub-electrode 38 may be connected to the first power line 39. In one setting, the first power line 39 may be a grid structure to achieve a smaller load.

Because the first substrate 49 may usually include copper material, and the copper material may have a better conductivity, the copper layer where the first substrate 49 is located may be used to further form the first power line 39. Moreover, the first power line 39 under this design may not affect the wiring of the metal wiring in the driving backplane 1, for example, it may not occupy the wiring space of the first electrode 8.

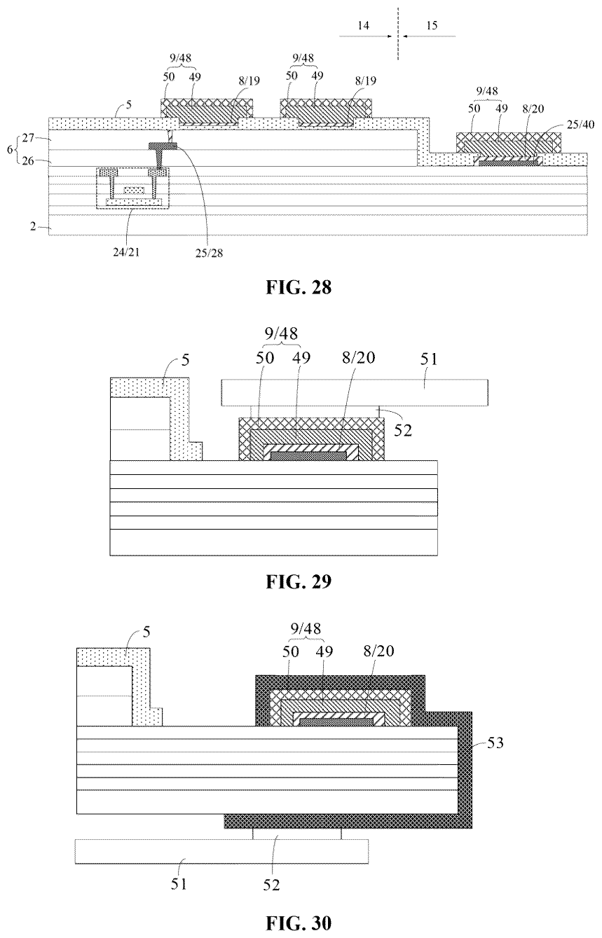

FIG. 27 is another structural schematic diagram of a display module provided by an embodiment of the present disclosure, and FIG. 28 is another structural schematic diagram of a display module provided by an embodiment of the present disclosure. As shown in FIG. 27 and FIG. 28, in one embodiment, the connection member 9 may include a first connection member 48, and the first connection member 48 may include a first substrate 49 and a first connection metal 50 covering the first substrate 49.

For the first sub-electrode 19 included in the first electrode 8, the first sub-electrode 19 may be electrically connected to the electrode of the light-emitting element 16 through the first connection member 48. For the second sub-electrode 20 included in the first electrode 8, the second sub-electrode 20 may also be electrically connected to the first connection member 48.

FIG. 29 is another structural schematic diagram of the display module provided by an embodiment of the present disclosure. As shown in FIG. 29, a portion of the first connection member 48 may be directly electrically connected to the pin 52 of the driving structure 51, or, as shown in FIG. 30, which is another structural schematic diagram of the display panel provided by an embodiment of the present disclosure, a portion of the first connection member 48 may also be electrically connected to the pin 52 of the driving structure 51 through the side wiring 53. The side wiring 53 may extend from the side of the driving backplane 1 to the back side.

In the above structure, the first connection member 48 may be formed on the first sub-electrode 19 and the second sub-electrode 20 by a chemical plating process, and there may be no need to design different connection members 9 for the two sub-electrodes, and the process may be simpler.

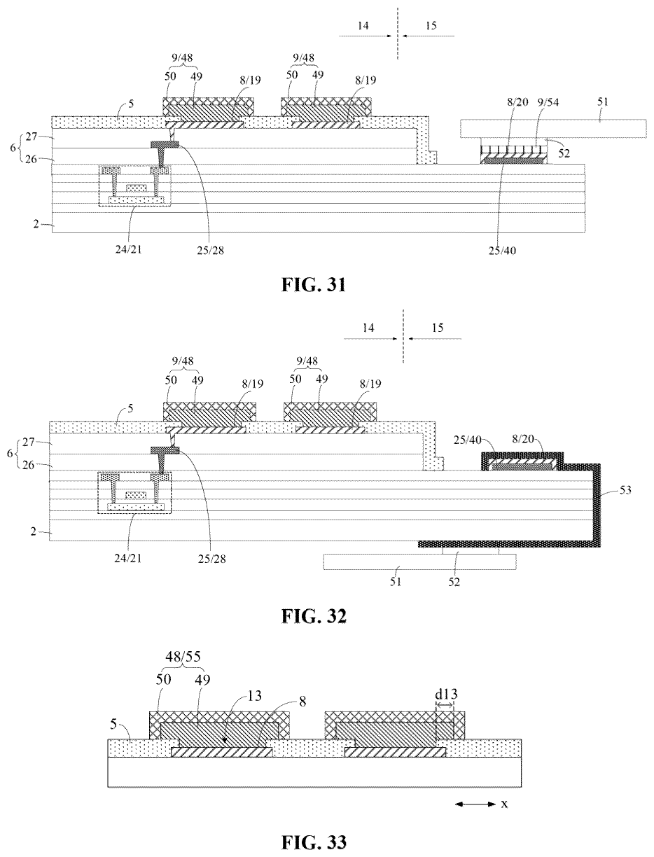

FIG. 31 is another structural schematic diagram of the display module provided by the embodiment of the present disclosure. As shown in FIG. 31, in one embodiment, the connection member 9 may include a second connection member 54. The second connection member 54 may include a conductive adhesive material, and the second sub-electrode 20 may also be electrically connected to the second connection member 54.

FIG. 32 is another structural schematic diagram of the display module provided by an embodiment of the present disclosure. As shown in FIG. 32, in another embodiment, the second sub-electrode 20 may also be connected to the side wiring 53. The side wiring 53 may extend from the side of the driving backplane 1 to the back side.

Regarding the second sub-electrode 20 in the first non-display area 15, a portion of the second sub-electrode 20 may be connected to the side wiring 53 by a direct contact, or by pressing and connecting the pin 52 of the driving structure 51 with a conductive adhesive material. In this way, the connection between the second sub-electrode 20 and the side wiring 53 or the driving structure 51 may be more direct, and the connection stability may be higher. When the second sub-electrode 20 is pressed and connected to the pin 52 of the driving structure 51 by a conductive adhesive material, the conductive adhesive material may be very thin and may not cause a large step difference, and the driving structure 51 may not be easy to be skewed after bonding.

In one embodiment, referring to FIG. 27, the first inorganic protective layer 5 may be at least located in the display area 14, and the edge of the first inorganic protective layer 5 may be located at the side of the second sub-electrode 20 adjacent to the display area 14. At this time, the second sub-electrode 20 may be completely exposed, and the contact area between the second sub-electrode 20 and the side wiring 53 or the connection member 9 may be large, and the connection stability may be higher. Moreover, because the second sub-electrode 20 in the embodiment of the present disclosure is formed of an anti-oxidation metal material, it may not be easy to be oxidized even if it is completely exposed.

In another embodiment, referring to FIG. 27, the planarization layer 6 may be at least located in the display area 14, and the edge of the planarization layer 6 may be located on the side of the second sub-electrode 20 adjacent to the display area 14 such that the planarization layer 6 at the position of the second sub-electrode 20 may be removed, which may facilitate the contact and connection between the second sub-electrode 20 and the second intermediate electrode 40. Further, the first inorganic protective layer 5 may also cover the sidewall of the planarization layer 6, and protect the side of the planarization layer 6 to prevent water and oxygen from penetrating through the side of the planarization layer 6.

Further, referring to FIG. 27, the edge of the first inorganic protective layer 5 may be located on the side of the second sub-electrode 20 adjacent to the display area 14, and the distance d8 between the edge of the first inorganic protective layer 5 and the edge of the planarization layer 6 may be greater than approximately 10 μm. At this time, the first inorganic protective layer 5 may extend a sufficient distance toward the second sub-electrode 20 compared with the planarization layer 6, thereby preventing water and oxygen from penetrating from the side of the planarization layer 6 to a greater extent.

In addition, unlike the planarization layer 6, referring to FIG. 21, the inorganic insulation layers in the circuit layer 3, such as the first inorganic insulation layer 43 and the second inorganic insulating layer 44, may be thinner and may be located on the side of the second intermediate electrode 40 facing the substrate 2, which may not affect the connection between the second sub-electrode 20 and the second intermediate electrode 40. Therefore, this portion of the inorganic insulation layer may cover the first non-display area 15 to isolate water and oxygen in the first non-display area 15.

FIG. 33 is another structural schematic diagram of a display module provided by an embodiment of the present disclosure. As shown in FIG. 33, in one embodiment, the connection member 9 may include a first connecting member 48. The first connection member 48 may include a first substrate 49 and a first connection metal 50 covering the first substrate 49.

The first connection member 48 may include a first sub-connection member 55, in which the first substrate 49 may be electrically connected to the first electrode 8 through the first connection hole 13 penetrating the first inorganic protective layer 5, and the first substrate 49 may cover the first connection hole 13, and there may be a gap between the edge of the first substrate 49 and the edge of the first connection hole 13 along the first direction x.

When the first connection member 48 is formed by a chemical plating process, the first substrate 49 may be first formed, and then metal may be generated on the surface of the first substrate 49, and the chemically plated metal may simultaneously grow upward on the top surface of the first substrate 49 and expand laterally on the side of the first substrate 49. When the first substrate 49 completely covers the first connection hole 13 and expands outward from the first connection hole 13, the side of the first substrate 49 may be exposed to the outside of the first inorganic protective layer 5, and the first inorganic protective layer 5 may not limit the metal that expands laterally on the side of the first substrate 49 such that it may grow laterally to the desired thickness.

Further, referring to FIG. 33, for the first sub-connection portion 55, along the first direction x, the distance d13 between the projection of the edge of the first substrate 49 and the projection of the edge of the first connection hole 13 is greater than approximately 5 μm such that the first substrate 49 may expand the first connection hole 13 by a sufficient distance. Such a configuration may not only allow the metal to grow normally on the side of the first substrate 49, but also enable the first sub-connection portion 55 to have a sufficiently large width in the first direction x for connection.

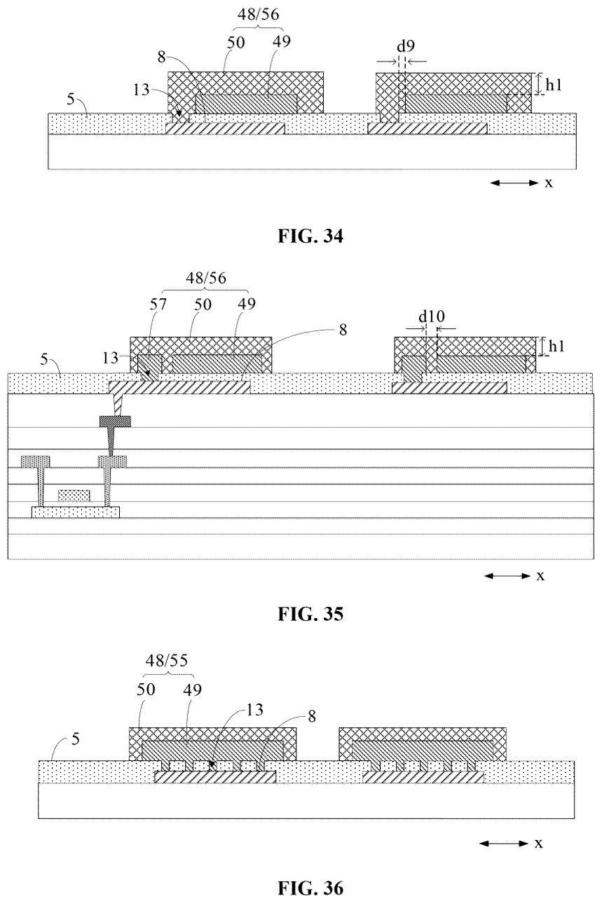

FIG. 34 is another structural schematic diagram of the display module provided by an embodiment of the present disclosure, and FIG. 35 is another structural schematic diagram of the display module provided by an embodiment of the present disclosure. As shown in FIG. 34 and FIG. 35, in one embodiment, the connection member 9 may include a first connection member 48. The first connection member 48 may include a first substrate 49 and a first connection metal 50 covering the first substrate 49.

The first connection member 48 may include a second sub-connection member 56, in which the first substrate 49 may be located on the side of the first inorganic protective layer 5 away from the substrate 2. The first connection metal 50 may overlap with the first connection hole 13, and the first connection metal 50 may be electrically connected to the first electrode 8.

In such a setting mode, the first substrate 49 may not be in direct contact with the first electrode 8, but may be electrically connected to the first electrode 8 through the chemically plated metal that grows laterally outward on the side of the first substrate 49. Because the first substrate 49 may not need to be accommodated in the first connection hole 13 of the first inorganic protective layer 5, the first connection hole 13 may be set slightly smaller to increase the coverage area of the first inorganic protective layer 5 and improve the protection performance of the first inorganic protective layer 5.

In another embodiment, referring to FIG. 34, in the second sub-connection member 56, the first connection metal 50 may be electrically connected to the first electrode 8 through the first connection hole 13, and along the first direction x, the distance d9 between the first substrate 49 and the first connection hole 13 may be less than h1. h1 may be the distance between the surface of the first connection metal 50 away from the substrate 2 and the surface of the first substrate 49 away from the substrate 2.

In the chemical plating process, the chemically plated metal may grow isotropically during its formation. Therefore, when the thickness of the first connection metal 50 growing upward on the top surface of the first substrate 49 is h1, it may mean that the first connection metal 50 may also need to expand outward laterally by h1. Setting the distance between the first substrate 49 and the first via hole 22 adjacent thereto to be less than h1 may ensure that the first connection metal 50 may grow laterally to the first via hole 22, and then be electrically connected to the lead-out electrode through the first via hole 22.

In another embodiment, referring to FIG. 35, the second sub-connection member 56 may also include a second substrate 57, which may be arranged in the same layer as the first substrate 49, and the second substrate 57 may be electrically connected to the first electrode 8 through the first connection hole 13, and the first connection metal 50 may also cover the second substrate 57.

The first substrate 49 may be formed by an etching process. When forming the first substrate 49, a whole layer of copper material may need to be deposited on the driving backplane 1 first, and then the copper material that may not need to be retained may be etched away using an etching solution.

A second substrate 57 may be further provided above the first electrode 8. On the one hand, the copper material above the first electrode 8 may need to be retained. Therefore, when etching the copper material with an etching solution, the etching solution may be prevented from contacting the first electrode 8 and causing contamination or corrosion to the lead-out electrode.

On the other hand, during the chemical plating process, metal may also be grown on the second substrate 57, and the metal grown on the second substrate 57 may be in contact with the first connection metal 50 to ensure the lead electrode to be on the first connection metal 50. Compared with only allowing the first connection metal 50 to be connected to the lead-out electrode through the first via hole 22, the connection reliability of the first connection metal 50 and the lead-out electrode in this way may be higher.

On the other hand, when the connection metal needs to have a larger size, the size of the connection metal may be increased by increasing the size of the first substrate 49. At this time, the second substrate 57 may be kept smaller, and the first connection hole 13 may have a smaller size accordingly, increasing the coverage area of the first inorganic protective layer 5.

Further, referring to FIG. 35, the distance d10 between the second substrate 57 and the first substrate 49 may be less than 2×h1. h1 may be the distance between the surface of the first connection metal 50 away from the substrate 2 and the surface of the first substrate 49 away from the substrate 2.

Combined with the above analysis of the chemically plated metal, the distance d10 between the second substrate 57 and the first substrate 49 may be less than 2×h1, which may ensure that the first connection metal 50 may be in contact with the connection metal formed on the surface of the second substrate 57 and connected together, thereby ensuring that the first connection metal 50 may be electrically connected to the lead-out electrode.

FIG. 36 is another structural schematic diagram of a display module provided by an embodiment of the present disclosure. As shown in FIG. 36, in one embodiment, at least a portion of the connection member 9 may be electrically connected to the first electrode 8 through a plurality of first connection holes 13 penetrating the first inorganic protective layer 5, and the plurality of first connection holes 13 overlapping the connection member 9 may be arranged at equal intervals. For example, for a plurality of first connection holes 13 overlapping the same connection member 9, the distances between adjacent first connection holes 13 in the first direction x may be equal. On the one hand, the plurality of first connection holes 13 may be used to reduce the contact resistance between the connection member 9 and the first electrode 8, and on the other hand, the plurality of first connection holes 13 arranged at equal intervals may also improve the flatness of the connection member 9.

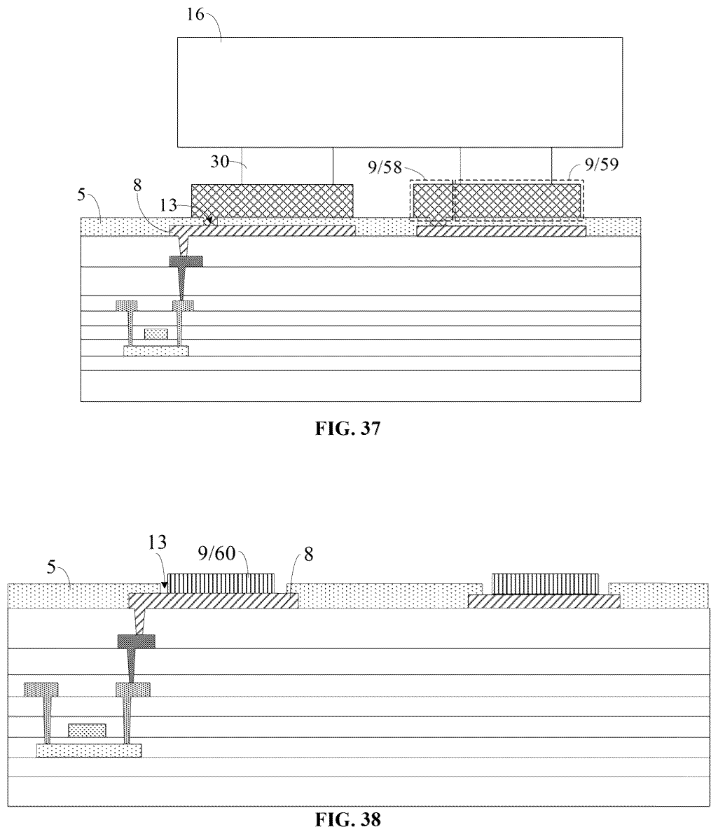

FIG. 37 is another structural schematic diagram of the display module provided by an embodiment of the present disclosure. As shown in FIG. 37, in one embodiment, for the connection member 9 electrically connected to the electrode 30 of the light-emitting element 16 through the first connection hole 13, the connection member 9 may include a first sub-member 58 and a second sub-member 59. In the direction perpendicular to the plane where the substrate 2 is located, the first sub-member 58 may overlap with the first connection hole 13, and the second sub-member 59 may overlap with the electrode 30 of the light-emitting element 16.

The first sub-member 58 may be in a non-bonding area in the connection member 9, and the second sub-member 59 may be in a bonding area in the connection member 9. Because the bonding area does not overlap with the first connection hole 13, the connection member 9 may be flatter in the bonding area, which may help to improve the bonding stability of the light-emitting element 16.

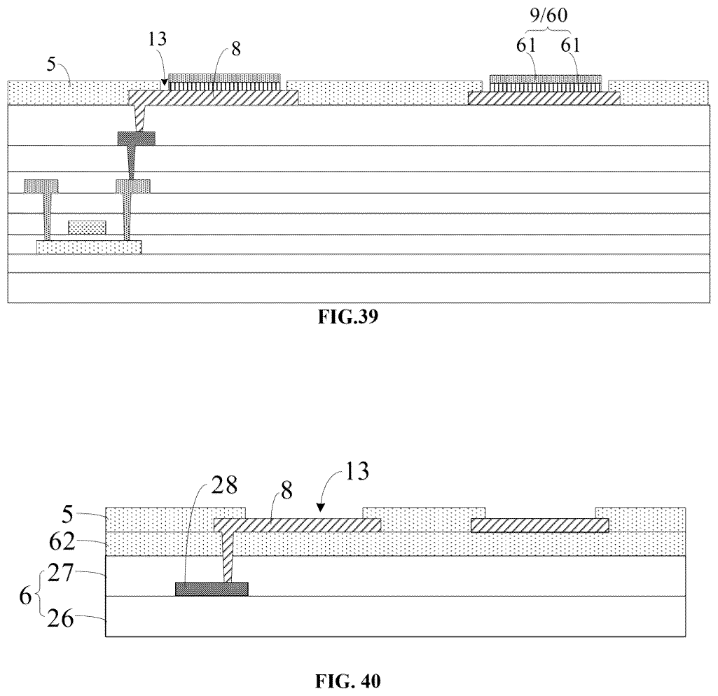

FIG. 38 is another structural schematic diagram of the display module provided by an embodiment of the present disclosure, and FIG. 39 is another structural schematic diagram of the display module provided by the embodiment of the present disclosure. As shown in FIG. 38 and FIG. 39, in one embodiment, the connection member 9 may include a third connection member 60. Referring to FIG. 38, the third connection member 60 may include only one metal material; or, referring to FIG. 39, the third connection member 60 may include at least two sub-metal layers 61, and the at least two sub-metal layers 61 may overlap only in a direction perpendicular to the plane where the substrate 2 is located.

This third connection member 60 may usually be formed by an evaporation process. First, a layer of metal may be formed by evaporation on the entire surface, then photoresist patterns may be made, and then portions of the photoresist may be removed to make the metal at some positions fall off, and the remaining metal may be the third connection member 60. This formation process may be relatively simple, and the overall thickness may be relatively thin.

Further, referring to FIG. 38 and FIG. 39, the first inorganic protective layer 5 may include a first connection hole 13 exposing the first electrode 8, and the third connection member 60 may be located in the first connection hole 13. At this time, the third connection member 60 may not form a step difference at the edge of the first connection hole 13, and the overall structure of the third connection member 60 may be flatter.

FIG. 40 is another structural schematic diagram of a display module provided by an embodiment of the present invention. As shown in FIG. 40, in one embodiment, the first electrode layer 7 may be located between the planarization layer 6 and the first inorganic protective layer 5.

The first film layer 4 may also include a second inorganic protective layer 62. The second inorganic protective layer 62 may be located between the first electrode layer 7 and the planarization layer 6.

In the process of such a structure, after the planarization layer 6 is formed, the second inorganic protective layer 62 may be formed first, and then the first inorganic protective layer 5 may be formed. The second inorganic protective layer 62 may only need to set the connection via hole between the first electrode 8 and the intermediate electrode 28, and the aperture of such connection via hole may be generally small. Thus, the second inorganic protective layer 62 may cover a larger area of the planarization layer 6 for more comprehensive protection.

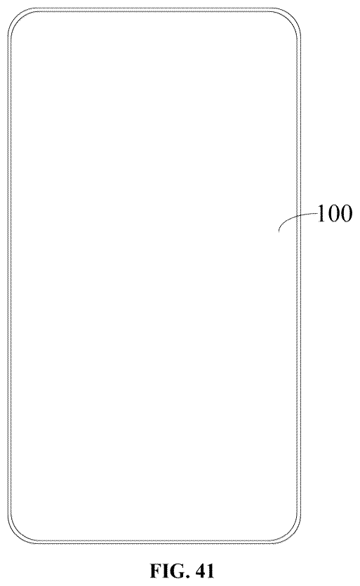

The present disclosure also provides a display device. FIG. 41 is a structural schematic diagram of a display device provided by an embodiment of the present disclosure. As shown in FIG. 41, the display device may include one of the above-mentioned display panels 100. The specific structure of the display panel 100 has been described in detail in the above embodiments, and will not be repeated here.

The display device shown in FIG. 41 is only for illustration. The display device provided in the embodiment of the present disclosure may be a non-spliced display product such as a mobile phone or a computer, or a spliced display product such as an outdoor large screen, etc.

The technical solutions of the present disclosure may include at least one of the following beneficial effects.

In the display panel provided by the embodiments of the present disclosure, the outermost insulation layer of the driving backplane may be the first inorganic protective layer, and the first inorganic protective layer may include an inorganic material. Compared with organic materials, inorganic materials may have better water and oxygen barrier properties, and thus the driving backplane may have better water and oxygen barrier properties.

For example, in the period from the completion of the production of the driving backplane to the formation of the connection member, the first inorganic protective layer may effectively block the water and oxygen in the environment to prevent the water and oxygen in the environment from penetrating into the driving backplane. When the connection member is subsequently formed by using an etching solution or other solution, the first inorganic protective layer may also effectively block the water and oxygen in the solution to prevent the water and oxygen in the solution from penetrating into the driving backplane. In this way, the water and oxygen resistance of the driving backplane may be effectively improved, the risk of oxidation of the first electrode may be reduced, and the connection reliability of the first electrode may be improved.

Further, there are currently multiple processes for forming the connection member. If a chemical plating process is used to form the connection member, when forming the connection member, a copper substrate needs to be formed first, and a stripping solution needs to be used when forming the copper substrate. The stripping solution may generally include an amine material. If the outermost insulation layer of the driving backplane is an organic layer, when the stripping liquid contacts the organic layer, the organic material and the amine material have drug resistance problems, and the two materials may react, resulting in film peeling, causing product defects and reliability risks. In the present disclosure, the outermost insulation layer of the driving backplane may be an inorganic layer. The inorganic material may not have drug resistance problems with the amine material, and may also separate the organic layer from the stripping liquid, preventing the stripping liquid from penetrating into the organic layer, thereby avoiding the stripping liquid from contacting the organic layer and reacting, and effectively solving the film peeling problem caused by the material drug resistance problem in the connection process.

The above are only preferred embodiments of the present disclosure and is not intended to limit the present disclosure. Any modifications, equivalent replacements, improvements, etc. made within the spirit and principles of the present disclosure should be included in the scope of protection of the present disclosure.

Finally, it should be noted that the above embodiments are only used to illustrate the technical solution of the present disclosure, not to limit it. Although the present disclosure is described in detail with reference to the above embodiments, ordinary technicians in this field should understand that they may still modify the technical solutions recorded in the above embodiments, or replace some or all of the technical features therein; and these modifications or replacements may not make the essence of the corresponding technical solutions deviate from the scope of the technical solutions of the embodiments of the present disclosure.

What is claimed is:

1. A display panel, comprising:
a driving backplane; and
a connection member located on one side of the driving backplane,
wherein the driving backplane includes:
a substrate;
a circuit layer over the substrate;
a first film layer located on a side of the circuit layer away from the substrate, wherein the first film layer includes a planarization layer and a first electrode layer, and the first electrode layer includes a first electrode; and
a first inorganic protective layer located on a side of the first film layer away from the substrate,
wherein at least a portion of the first electrode is exposed by the first inorganic protective layer, and the connection member is electrically connected to the first electrode.

2. The display panel according to claim 1, wherein:
the first electrode layer is located between the planarization layer and the first inorganic protective layer; and
the first inorganic protective layer includes a first connection hole exposing the first electrode, and in a direction perpendicular to the plane where the substrate is located, a projection of an edge of the first connection hole is located within a projection of the first electrode.

3. The display panel according to claim 2, comprising:
a display area; and
a first non-display area,
wherein:
the display area includes a light-emitting element and a first signal line;
the first non-display area includes a connection signal line electrically connected to the first signal line, wherein at least a portion of the first signal line and/or at least a portion of the connection signal line is located in the circuit layer;
the first electrode includes a first sub-electrode and a second sub-electrode;
the first sub-electrode is located in the display area and electrically connected to the light-emitting element;
the second sub-electrode is located in the first non-display area and electrically connected to the connection signal line;
the first connection hole includes a first via hole exposing the first sub-electrode; and/or
the first connection hole includes a second via hole exposing the second sub-electrode.

4. The display panel according to claim 2, wherein the circuit layer comprises:
a first structure,
wherein:
the first film layer also includes a second electrode layer;
the planarization layer includes a first planarization layer and a second planarization layer;
the first planarization layer is located between the second electrode layer and the circuit layer;
the second planarization layer is located between the first electrode layer and the second electrode layer;
the second electrode layer includes an intermediate electrode; and
at least a portion of the first electrode is electrically connected to the first structure through the intermediate electrode.

5. The display panel according to claim 4, wherein:
an area of an orthographic projection of the first electrode on the substrate is larger than an area of an orthographic projection of the intermediate electrode connected thereto on the substrate; or
the first inorganic protective layer includes a first connection hole exposing the first electrode, wherein the at least portion of the first electrode is also electrically connected to the intermediate electrode through a second connection hole penetrating the second planarization layer, and an aperture of the first connection hole is larger than an aperture of the second connection hole; or
the display panel includes a display area including a light-emitting element, wherein the first electrode includes a first sub-electrode located in the display area and electrically connected to an electrode of the light-emitting element, the first inorganic protective layer includes a first connection hole exposing the first electrode; the first connection hole includes a first via hole exposing the first sub-electrode; and an area of an orthographic projection of the first via hole on the substrate is larger than an area of an orthographic projection of the electrode of the light-emitting element connected thereto on the substrate.

6. The display panel according to claim 4, wherein the first inorganic protective layer comprises:
a first connection hole exposing the first electrode,
wherein:
the at least portion of the first electrode is also electrically connected to the intermediate electrode through a second connection hole penetrating the second planarization layer; and
for the first connection hole and the second connection hole overlapping the same first electrode, the second connection hole does not overlap with the first connection hole.

7. The display panel according to claim 6, wherein:
the first electrode includes a first edge and a second edge opposite to each other, wherein, for the first connection hole and the second connection hole overlapping the same first electrode, along a first direction, a distance between the first connection hole and the first edge is equal to a distance between the first connection hole and the second edge, the first direction is parallel to the plane where the substrate is located, and an orthographic projection of the second connection hole on the substrate is located between an orthographic projection of the first connection hole on the substrate and an orthographic projection of the first edge on the substrate; or
the first electrode includes a first edge and a second edge opposite to each other, wherein, for the first connection hole and the second connection hole overlapping the same first electrode, along a first direction, a distance between the first connection hole and the first edge is greater than a distance between the first connection hole and the second edge and a distance between the second connection hole and the first edge is less than a distance between the second connection hole and the second edge, and the first direction is parallel to the plane where the substrate is located.

8. The display panel according to claim 4, wherein:
the display panel includes a display area including a light-emitting element, wherein the first electrode includes a first sub-electrode electrically connected to the light-emitting element, the first sub-electrode includes a second type of first sub-electrode the second type of first sub-electrode is also electrically connected to a first power line, and the first power line is located in the first electrode layer; or
the display panel includes a display area and a first non-display area, wherein the display area includes a first signal line, the first structure includes a connection signal line, the connection signal line is located in the first non-display area and is electrically connected to the first signal line, the intermediate electrode includes a second intermediate electrode located in the first non-display area, the first electrode includes a second sub-electrode located in the first non-display area, the second sub-electrode is electrically connected to the connection signal line through the second intermediate electrode, an edge of the second planarization layer is located on a side of the second sub-electrode adjacent to the display area, and the second sub-electrode covers the second intermediate electrode.

9. The display panel according to claim 4, comprising:
a display area; and
a first non-display area,
wherein:
the display area includes a first signal line;
the first structure includes a connection signal line;
the connection signal line is located in the first non-display area and is electrically connected to the first signal line;
the intermediate electrode includes a second intermediate electrode located in the first non-display area;
the first electrode includes a second sub-electrode;
the second sub-electrode is located in the first non-display area and is electrically connected to the second intermediate electrode;
the circuit layer also includes a first connection electrode and a second connection electrode;
a first inorganic insulation layer is included between the first connection electrode and the second connection electrode;
a second inorganic insulation layer is included between the second connection electrode and the second intermediate electrode;
the second intermediate electrode is electrically connected to the second connection electrode through at least two third connection holes penetrating the second inorganic insulation layer;
the second connection electrode is electrically connected to the first connection electrode through at least two fourth connection holes penetrating the first inorganic insulation layer; and
the connection signal line is electrically connected to the first connection electrode and/or the second connection electrode.

10. The display panel according to claim 9, wherein:
in a direction perpendicular to the plane where the substrate is located, the third connection hole and the fourth connection hole do not overlap; or
in a direction perpendicular to the plane where the substrate is located, the second intermediate electrode covers the second connection electrode, along a first direction, there is a gap between an edge of the second intermediate electrode and an edge of the second connection electrode, the first direction is parallel to the plane where the substrate is located, in the direction perpendicular to the plane where the substrate is located, the second connection electrode covers the first connection electrode, and along the first direction, there is a gap between a projection of an edge of the second connection electrode and a projection of an edge of the first connection electrode.

11. The display panel according to claim 4, wherein the first inorganic protective layer comprises:
a first connection hole exposing the first electrode, wherein, in a direction perpendicular to the plane of the substrate, for the first connection hole and the intermediate electrode overlapping the same first electrode, at least a portion of the first connection hole does not overlap with the intermediate electrode.

12. The display panel according to claim 2, wherein the circuit layer comprises:
a first structure,
wherein:
the first film layer includes a first planarization layer;
the first planarization layer is located between the first electrode layer and the circuit layer; and
at least a portion of the first electrode is electrically connected to the first structure through a fifth connection hole penetrating the first planarization layer.

13. The display panel according to claim 12, wherein:
a surface of the first inorganic protective layer facing the substrate is in contact with a surface of the first planarization layer away from the substrate; and/or
the first film layer further includes a second planarization layer located on a side of the first electrode layer away from the substrate, wherein the first inorganic protective layer is located on a side of the second planarization layer away from the substrate.

14. The display panel according to claim 1, wherein:
the connection member includes a first connection member;
the first connection member includes a first substrate and a first connection metal covering the first substrate;
the display panel includes a display area and a first non-display area;
the display area includes a light-emitting element and a first signal line;
the first non-display area includes a connection signal line electrically connected to the first signal line;
the first electrode includes a first sub-electrode and a second sub-electrode;
the first sub-electrode is located in the display area and is electrically connected to the light-emitting element through the first connection member; and
the second sub-electrode is located in the first non-display area and is electrically connected to the connection signal line and the first connection member, respectively.

15. The display panel according to claim 1, wherein:
the display panel includes a display area and a first non-display area;
the display area includes a first signal line;
the first non-display area includes a connection signal line electrically connected to the first signal line;
the first electrode includes a second sub-electrode;
the second sub-electrode is located in the first non-display area and is electrically connected to the connection signal line;
the connection member includes a second connection member;
the second connection member includes a conductive adhesive material;
the second sub-electrode is also electrically connected to the second connection member;
or
the second sub-electrode is also in contact with a side wiring and the side wiring extends from a side of the driving backplane to a back of the driving backplane.

16. The display panel according to claim 1, wherein:
the display panel includes a display area and a first non-display area;
the display area includes a first signal line;
the first non-display area includes a connection signal line electrically connected to the first signal line;
the first electrode includes a second sub-electrode;
the second sub-electrode is located in the first non-display area and is electrically connected to the connection signal line;
the first inorganic protective layer is at least located in the display area; and
an edge of the first inorganic protective layer is located on a side of the second sub-electrode adjacent to the display area.

17. The display panel according to claim 1, wherein:
the display panel includes a display area and a first non-display area;
the display area includes a first signal line;
the first non-display area includes a connection signal line electrically connected to the first signal line;
the first electrode includes a second sub-electrode;
the second sub-electrode is located in the first non-display area and is electrically connected to the connection signal line;
the planarization layer is at least located in the display area;
an edge of the planarization layer is located on a side of the second sub-electrode adjacent to the display area; and
the first inorganic protective layer covers a sidewall of the planarization layer.

18. The display panel according to claim 17, wherein:
the edge of the first inorganic protective layer is located on a side of the second sub-electrode adjacent to the display area; and
a distance between an edge of the first inorganic protective layer and an edge of the planarization layer is greater than approximately 10 μm.

19. The display panel according to claim 1, wherein:
the connection member includes a third connection member;
the third connection member includes only one metal material; or
the third connection member includes at least two sub-metal layers, and the at least two sub-metal layers overlap only in a direction perpendicular to a plane where the substrate is located.

20. A display device, comprising:
a display panel including a driving backplane and a connection member located on one side of the driving backplane,
wherein the driving backplane includes:
a substrate;
a circuit layer over the substrate;
a first film layer located on a side of the circuit layer away from the substrate, wherein the first film layer includes a planarization layer and a first electrode layer, and the first electrode layer includes a first electrode; and
a first inorganic protective layer located on a side of the first film layer away from the substrate,
wherein at least a portion of the first electrode is exposed by the first inorganic protective layer, and the connection member is electrically connected to the first electrode.
